(19) United States
(12) Patent Application Publication
(10) Pub. No.: US 2026/0107432 A1
(43) Pub. Date: Apr. 16, 2026

(54) CFET SRAM DEVICE, LAYOUT, AND METHOD

(71) Applicant: TAIWAN SEMICONDUCTOR MANUFACTURING COMPANY, LTD., Hsinchu (TW)

(72) Inventors: Yung-Ting CHANG, Hsinchu (TW); Jui-Lin CHEN, Hsinchu (TW); Ping-Wei WANG, Hsinchu (TW)

(21) Appl. No.: 19/058,445

(22) Filed: Feb. 20, 2025

Related U.S. Application Data
(60) Provisional application No. 63/707,609, filed on Oct. 15, 2024.

(51) Int. Cl. H10B 10/00; G06F 30/32

(52) U.S. Cl. CPC H10B 10/125; G06F 30/32

(57) ABSTRACT

An IC device includes a static random-access memory (SRAM) device positioned in a substrate, the SRAM device including a first complementary field-effect transistor (CFET) including a first pass-gate transistor positioned at a first elevation, a second CFET including a first pull-down transistor positioned at the first elevation and a first pull-up transistor positioned at a second elevation, a third CFET including a second pull-down transistor positioned at the first elevation and a second pull-up transistor positioned at the second elevation, and a fourth CFET including a second pass-gate transistor positioned at the first elevation. Each of the first and second pull-down transistors includes a gate extending in a gate direction and including a first work function configuration, and each of the first and second pass-gate transistors includes a gate extending in the gate direction and including a second work function configuration different from the first work function configuration.

### PRIORITY CLAIM

The present application claims the priority of U.S. Provisional Application No. 63/707,609, filed Oct. 15, 2024, which is incorporated herein by reference in its entirety.

### BACKGROUND

The ongoing trend in miniaturizing integrated circuits (ICs) has resulted in progressively smaller devices which consume less power, yet provide more functionality at higher speeds than earlier technologies. Such miniaturization has been achieved through design and manufacturing innovations tied to increasingly strict specifications. Various electronic design automation (EDA) tools are used to generate, revise, and verify designs for semiconductor devices while ensuring that IC structure design and manufacturing specifications are met.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of a memory cell, in accordance with some embodiments.

FIGS. 2A-2C are plan views of an IC device and layout diagram, in accordance with some embodiments.

FIGS. 3A-3E are plan and cross-sectional views of an IC device and layout diagram, in accordance with some embodiments.

FIGS. 4A-4C are a schematic diagram and plan and cross-sectional views of an IC device and layout diagram, in accordance with some embodiments.

FIGS. 5A and 5B are plan views of an IC device and layout diagram, in accordance with some embodiments.

FIG. 6 is a plan view of an IC device and layout diagram, in accordance with some embodiments.

FIG. 7 is a cross-sectional view of an IC device and layout diagram, in accordance with some embodiments.

FIG. 8 is a flowchart of a method of manufacturing an IC device, in accordance with some embodiments.

FIG. 9 is a flowchart of a method of generating an IC layout diagram, in accordance with some embodiments.

FIG. 10 is a block diagram of an IC layout diagram generation system, in accordance with some embodiments.

FIG. 11 is a block diagram of an IC manufacturing system, and an IC manufacturing flow associated therewith, in accordance with some embodiments.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In various embodiments, an integrated circuit (IC) device, layout diagram, and manufacturing method are directed to a static random-access memory (SRAM) device including complementary field-effect transistors (CFETs) in which first and second pass-gate transistors are positioned at a first elevation and include gates having a first work function configuration, and first and second pull-down transistors are positioned at the first elevation and include gates having a second work function configuration different from the first work function configuration.

By including gates having different work function configurations, the pass-gate and pull-down transistors are capable of having tunable relative threshold voltage levels such that, compared to other approaches, e.g., those in which pass-gate and pull-down transistors have a same threshold voltage level, the SRAM device is capable of having improved read current properties, thereby enabling operation at reduced power supply levels, and for a given power supply voltage level, enabling shortened read windows corresponding to relatively higher operating speeds.

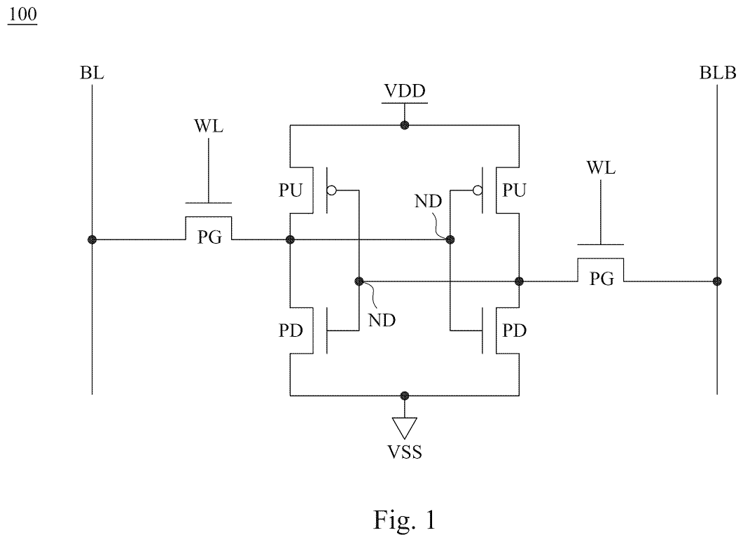

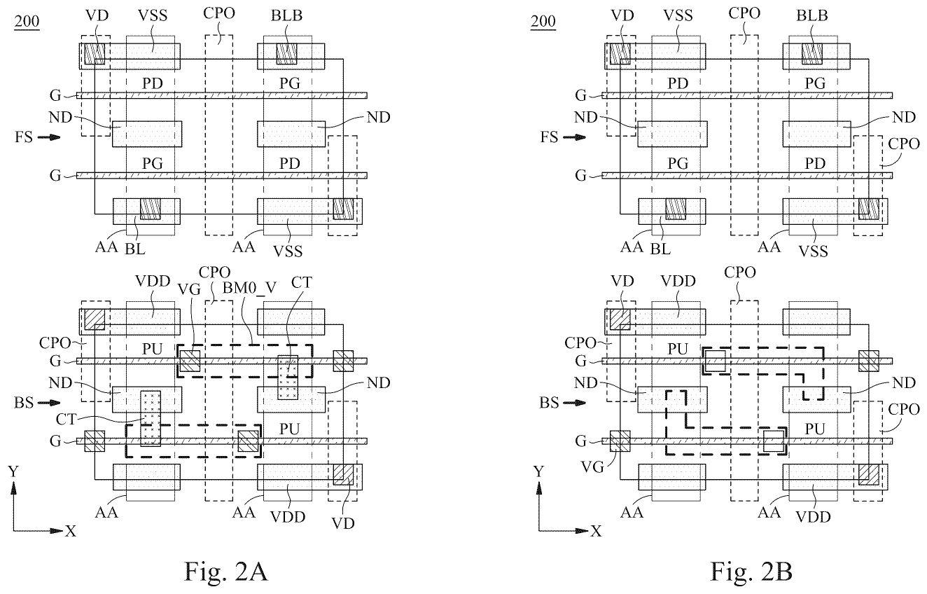

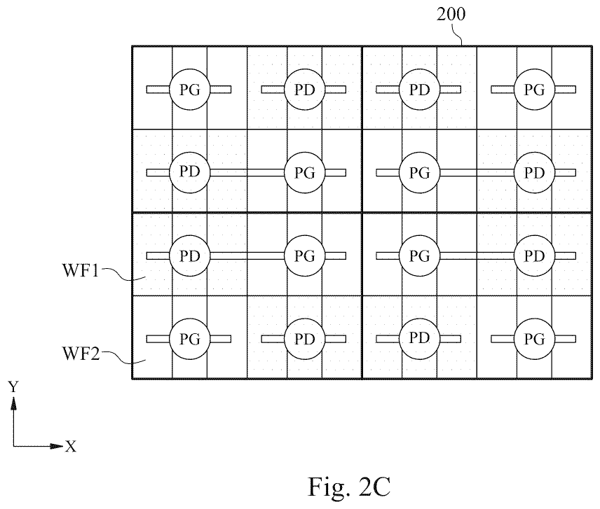

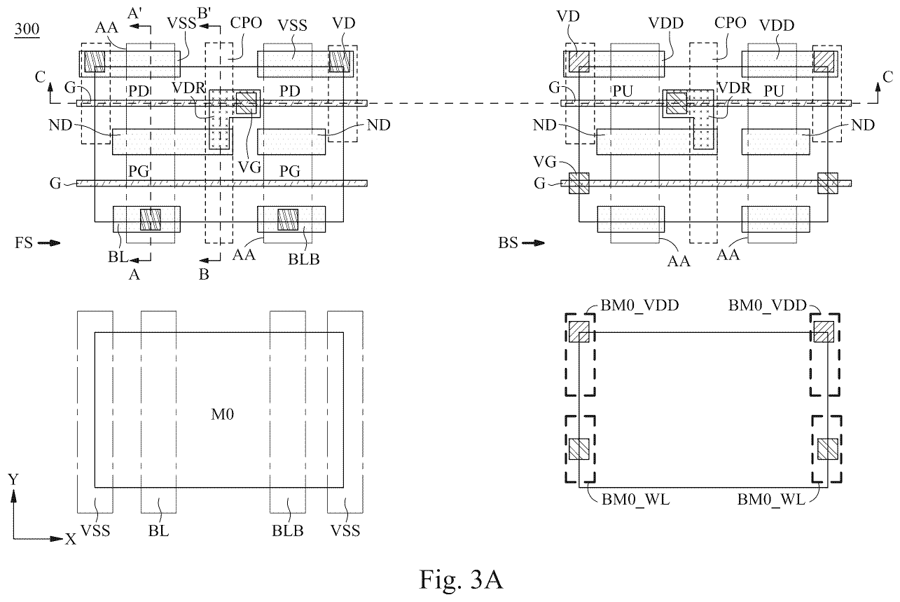

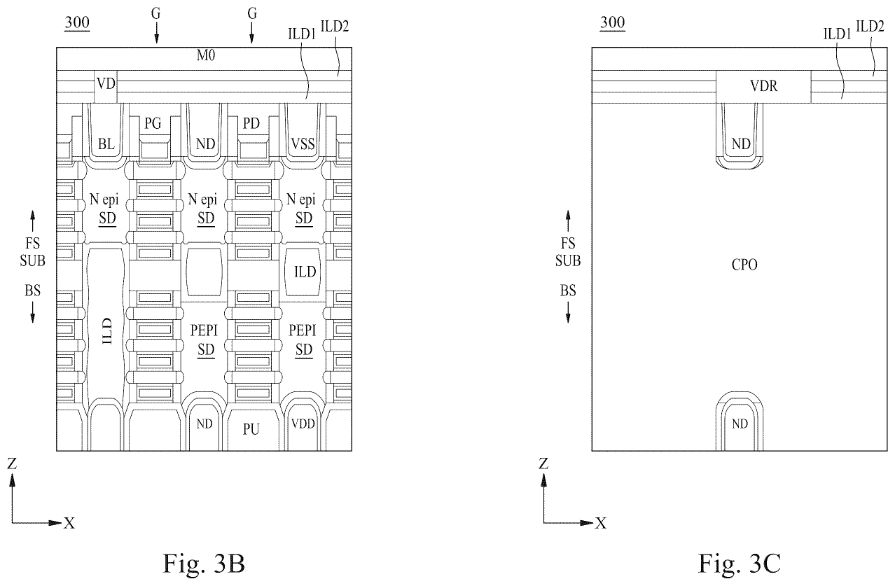

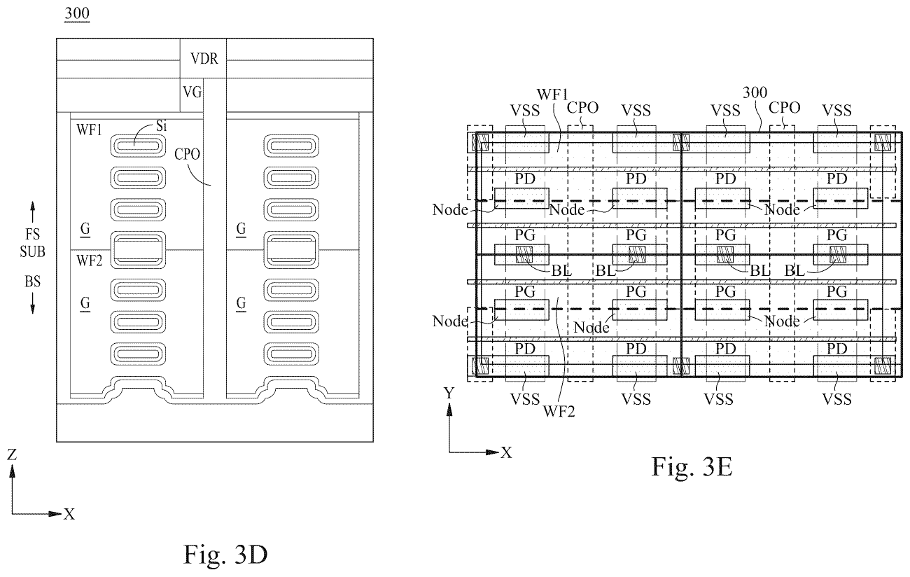

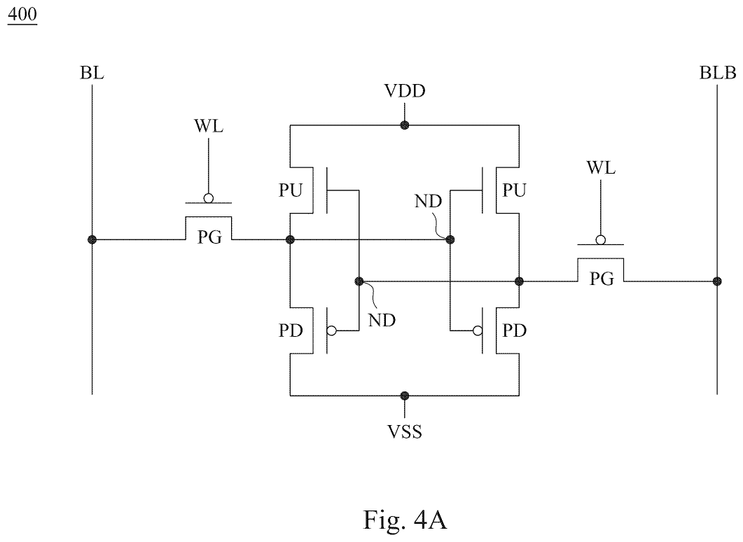

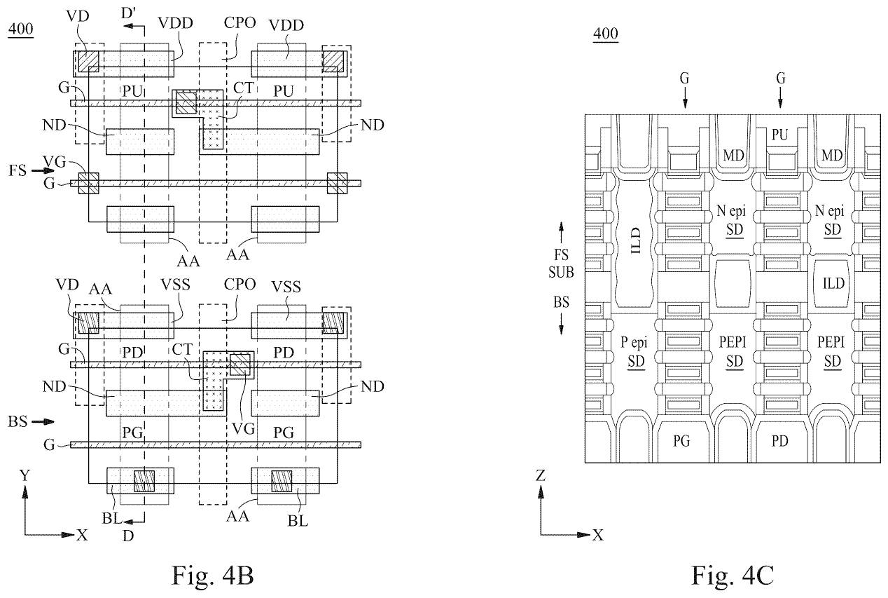

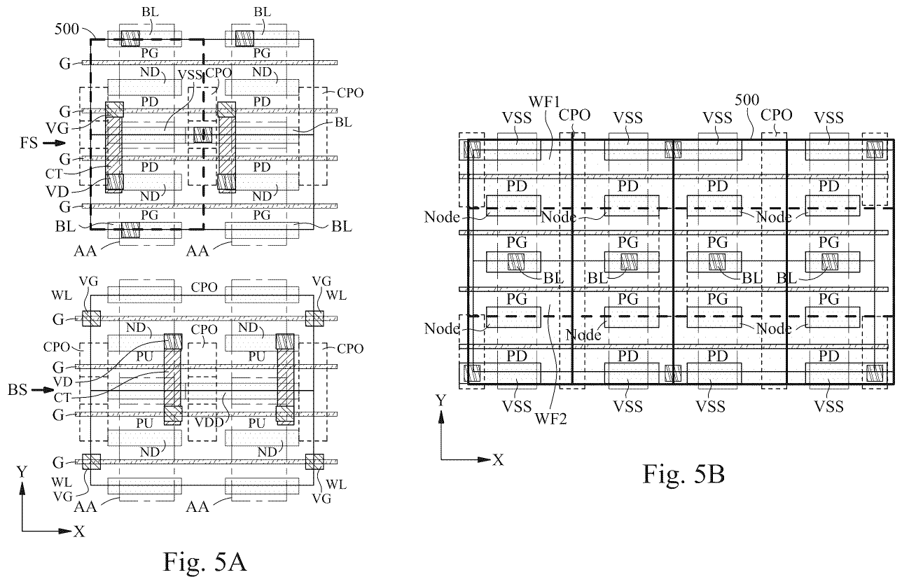

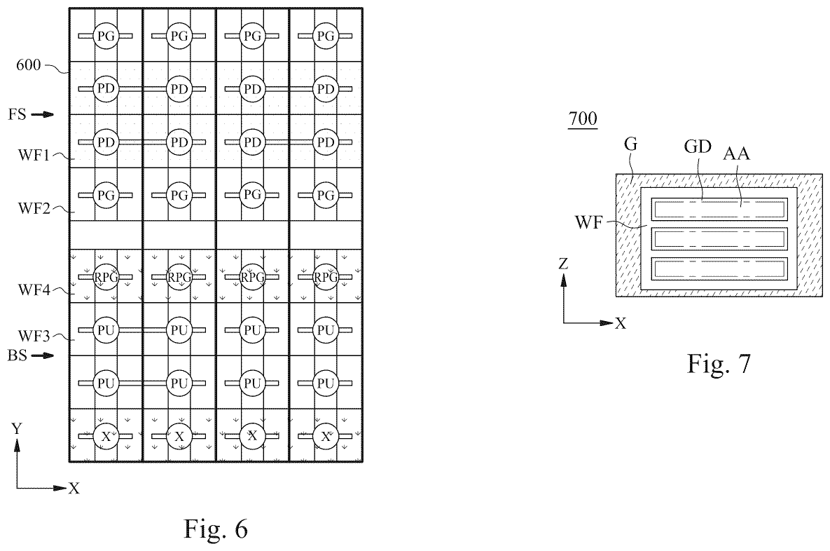

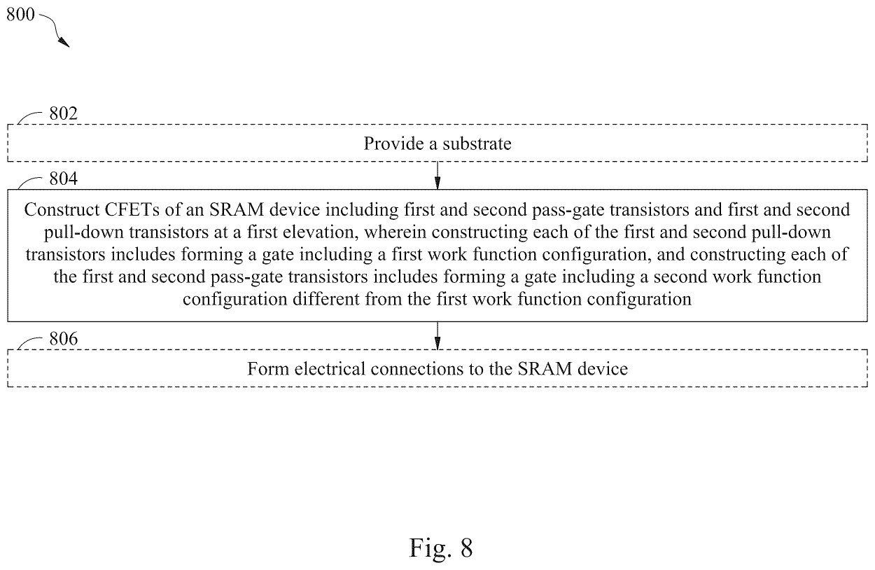

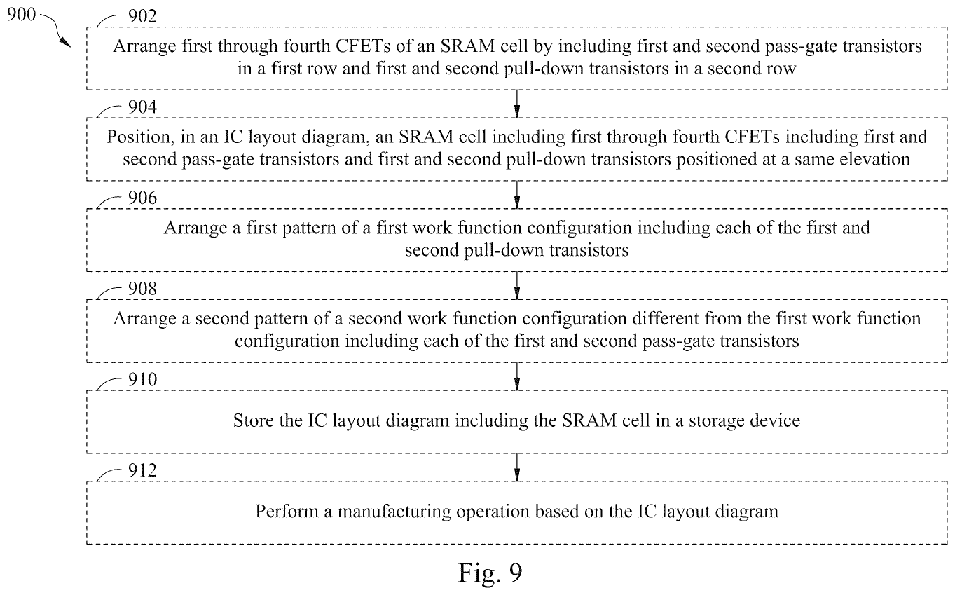

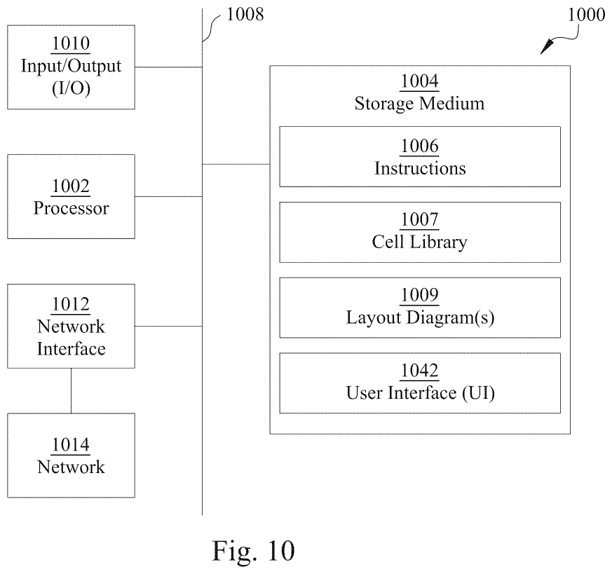

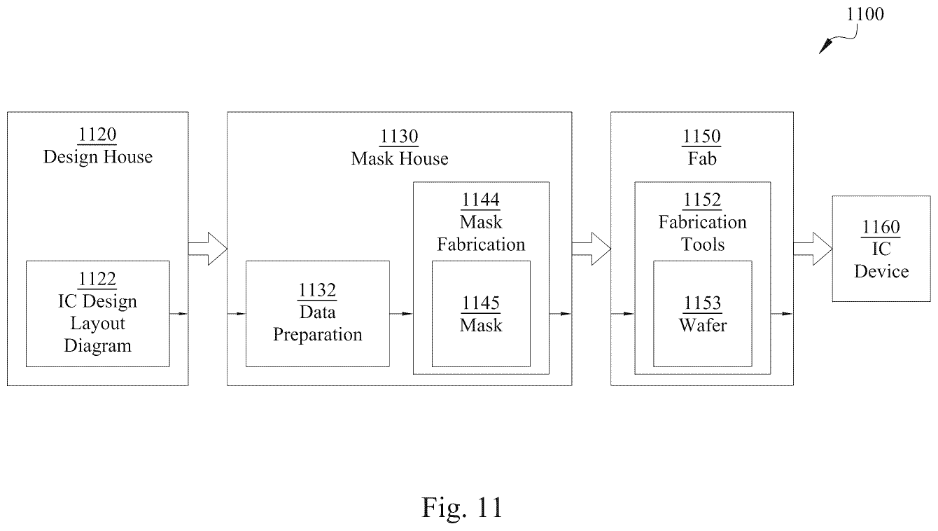

As discussed below, in accordance with various embodiments, FIG. 1 is a schematic diagram of a memory cell 100, FIGS. 2A-2C are plan views of an IC device and layout diagram 200, FIGS. 3A-3E are plan and cross-sectional views of an IC device and layout diagram 300, FIGS. 4A-4C are plan and cross-sectional views of an IC device and layout diagram 400, FIGS. 5A and 5B are plan views of an IC device and layout diagram 500, FIG. 6 is a plan view of an IC device and layout diagram 600, FIG. 7 is a cross-sectional view of an IC device and layout diagram 700, FIG. 8 is a flowchart of a method 800 of manufacturing an IC, and FIG. 9 is a flowchart of a method 900 of generating an IC layout diagram, e.g., using an IC layout diagram generation system 1000 depicted in FIG. 10 and/or in accordance with an IC manufacturing flow 1100 depicted in FIG. 11.

Each of the figures herein, e.g., FIGS. 1-7, is simplified for the purpose of illustration. The figures are views of IC schematics, structures, devices, and layout diagrams with various features included and excluded to facilitate the discussion below. In various embodiments, an IC, structure, device and/or layout diagram includes one or more features corresponding to power distribution structures, metal interconnects, contacts, vias, gate structures, source/drain (S/D) structures, active areas, bulk connections, or other transistor elements, isolation structures, or the like, in addition to the features depicted in FIGS. 1-7.

In each of IC layout diagrams/devices 200-700, reference designators represent both IC device features and the IC layout features used to at least partially define the corresponding IC device features in a manufacturing process, e.g., method 800 discussed below with respect to FIG. 8 and/or the IC manufacturing flow associated with IC manufacturing system 1100 discussed below with respect to FIG. 11. Accordingly, each of IC layout diagrams/devices 200-700 represents a view of both an IC layout diagram 200-700 and a corresponding IC device 200-700.

Each of IC layout diagrams/devices 200-700 discussed below includes arrangements of some or all of at least one of a substrate, an active region/area, a S/D region/structure, a contact and/or interconnect region/structure, a gate region/structure, a metal region/segment, a via region/structure, and/or a dielectric region/layer, each discussed below.

A substrate, e.g., a substrate SUB, is a portion, e.g., a die, or all of a semiconductor or other wafer, e.g., a silicon (Si) wafer, or an epitaxial Si layer, suitable for forming one or more IC devices, e.g., IC devices 200-600. In each of the embodiments discussed below, a substrate, e.g., a semiconductor substrate, includes a front side, e.g., a front side FS, within which a first subset of the features of the IC devices are formed through a first set of manufacturing processes, e.g., front-end-of-line (FEOL) processes, middle-end-of-line (MEOL) processes, and back-end-of-line (BEOL) processes, and a back side, e.g., a back side BS, within which a second subset of the features of the IC devices are formed through a second set of manufacturing processes, e.g., backside metallization processes, performed after the first set of manufacturing processes are performed.

An active region/area, e.g., an active region/area AA, is a region in an IC layout diagram included in a manufacturing process as part of defining an active area, also referred to as an oxide diffusion or definition (OD) in some embodiments, in the substrate, either directly or in an n-well or p-well region/area, in which one or more IC device features, e.g., a S/D structure, is formed. In some embodiments, an active area is an n-type or p-type active area of a stacked complementary field-effect transistor (CFET) or another transistor configuration including a gate region/structure.

In various embodiments, an active area (structure) includes one or more of a semiconductor material, e.g., silicon (Si), silicon-germanium (SiGe), silicon-carbide (SiC), or the like, a dopant material, e.g., boron (B), aluminum (Al), phosphorous (P), arsenic (As), gallium (Ga), or another suitable material.

In some embodiments, an active region is a region in an IC layout diagram included in the manufacturing process as part of defining a nano-sheet structure, e.g., a continuous volume of one or more layers of one or more semiconductor materials having either n-type or p-type doping. In various embodiments, individual nano-sheet layers include a single monolayer or multiple monolayers of a given semiconductor material.

A S/D region/structure, e.g., an S/D region/structure SD, is a region in the IC layout diagram included in the manufacturing process as part of defining a S/D structure, also referred to as a semiconductor structure in some embodiments, configured to have a doping type opposite that of the corresponding active region/area. In some embodiments, a S/D region/structure is configured to have lower resistivity than an adjacent channel feature, e.g., a portion of the corresponding active region/area of a CFET or other transistor. In some embodiments, a S/D region/structure includes one or more portions having doping concentrations greater than one or more doping concentrations present in the corresponding channel feature. In some embodiments, a S/D region/structure includes one or more epitaxial regions of a semiconductor material, e.g., Si, SiGe, and/or silicon-carbide SiC. A S/D region/structure, also referred to as a S/D terminal in some embodiments, may refer to a source or a drain, individually or collectively, dependent upon the context.

A contact or interconnect region/structure, e.g., a contact region/structure CT or an interconnect region/structure ND or Node, is a conductive region in the IC layout diagram included in the manufacturing process as part of defining a contact or interconnect structure, also referred to as a conductive segment or metal-like defined (MD) conductive line, trace, or structure, in and/or on the substrate. In some embodiments, a contact or interconnect region overlaps an active area at a location of one or more S/D regions in the IC layout diagram, and the corresponding contact or interconnect structure contacts and is electrically connected to the one or more S/D structures of the active area.

In some embodiments, a contact or interconnect structure includes a portion of at least one metal layer, e.g., a contact layer, overlying and contacting the substrate and having a thickness sufficiently small to enable formation of an insulation layer between the contact or interconnect structure and an overlying metal layer, e.g., the first metal layer. In various embodiments, an MD segment includes one or more of copper (Cu), silver (Ag), tungsten (W), titanium (Ti), nickel (Ni), tin (Sn), aluminum (Al) or another metal or material suitable for providing a low resistance electrical connection between IC structure elements, i.e., a resistance level below a predetermined threshold corresponding to one or more tolerance levels of a resistance-based effect on circuit performance.

In various embodiments, a contact or interconnect structure includes a section of a substrate and/or an epitaxial layer having a doping level, e.g., based on an implantation process, sufficient to cause the structure to have the low resistance level. In various embodiments, a doped contact or interconnect structure includes one or more dopant materials having doping concentrations of about 1*1016 per cubic centimeter (cm-3) or greater.

In some embodiments, a manufacturing process includes two or more contact or interconnect structure layers, and a contact or interconnect region/structure, e.g., contact region/structure CT or interconnect region/structure ND or Node, refers to one or more of the two or more contact or interconnect structure layers in the manufacturing process. In some embodiments, a contact or interconnect structure is configured to be electrically connected to the S/D structure of a single one of a p-type or n-type FET of a CFET, and to be electrically isolated from the S/D structure of the other of the p-type or n-type FET of the CFET. In some embodiments, a contact or interconnect structure, also referred to as an MD local interconnect (MDLI), or local interconnect (LI) in some embodiments, is configured to be electrically connected to the S/D structures of both the p-type FET and the n-type FET of a CFET.

A gate region/structure, e.g., a gate region/structure G, also referred to as a gate G in some embodiments, is a region in the IC layout diagram included in the manufacturing process as part of defining a gate structure. A gate structure is a volume including one or more conductive segments, e.g., a gate electrode, including one or more conductive materials, e.g., polysilicon, copper (Cu), aluminum (Al), tungsten (W), cobalt (Co), ruthenium (Ru), or one or more other metals or other suitable materials, substantially surrounded by one or more insulating materials, the one or more conductive segments thereby being configured to control a voltage provided at one or more adjacent gate dielectric layers, e.g., adjacent to or surrounding one or more channel regions of a corresponding active area.

A gate dielectric layer, e.g., a gate dielectric layer GD of a gate structure G, is a volume including one or more insulating materials, e.g., silicon dioxide, silicon nitride (Si₃N₄), and/or one or more other suitable material such as a low-k material having a k value less than 3.8 or a high-k material having a k value greater than 3.8 or 7.0 such as aluminum oxide (Al₂O₃), hafnium oxide (HfO₂), tantalum pentoxide (Ta₂O₅), or titanium oxide (TiO₂), suitable for providing a high electrical resistance between IC structure elements, i.e., a resistance level above a predetermined threshold corresponding to one or more tolerance levels of a resistance-based effect on circuit performance.

A work function configuration, e.g., a work function configuration WF1-WF4, is one or more regions in the IC layout diagram included in the manufacturing process as part of defining one or more layers of work function materials positioned within a transistor gate electrode adjacent to the corresponding one or more gate dielectric layers.

The one or more layers of work function materials include n-type and/or p-type work function materials having one or more thicknesses, concentration levels, dopants, impurities, or the like, configured to increase or decrease a work function of the gate electrode by a target value compared to a work function of an equivalent gate electrode that does not include the one or more layers of work function materials. Non-limiting examples of work function materials include Ti, Ag, Al, TaAl, TaAlC, TiAlN, TaC, TaCN, TaSiN, Mn, and Zr.

A threshold voltage level of a transistor is a function of operating conditions, e.g., voltage bias levels and/or temperature, in combination with the work function of the corresponding gate electrode. For a predetermined set of operating conditions, e.g., within predetermined voltage and/or temperature ranges, a given target value of the work function increase or decrease translates to an increase or decrease in the threshold voltage level of the transistor that includes the corresponding gate compared to a threshold voltage level of an equivalent transistor having the equivalent gate electrode that does not include the one or more layers of work function materials.

Each work function configuration thereby corresponds to a predetermined threshold voltage level of the corresponding transistor such that a plurality of work function configurations is usable to define a predetermined number of threshold voltage levels.

In some embodiments, a gate region/structure corresponds to a dummy gate region/structure. In some embodiments, a dummy gate region/structure includes a gate electrode electrically connected, e.g., tied-off, to one or more features, e.g., a power rail or other metal segment or an adjacent instance of a S/D region/structure such that a transistor corresponding to the dummy gate region/structure and overlapping/underlying active region/area is switched off by design. In some embodiments, a dummy gate region/structure that overlaps/overlies an edge of an active region/area is referred to as a continuous poly on oxide definition edge (CPODE) region/structure.

A cut-gate region, e.g., a cut-gate region CPO, also referred to as a cut-poly region in some embodiments, is a region in the IC layout diagram included in the manufacturing process as part of defining a discontinuity in a given gate structure, e.g., a portion etched away after the gate electrode has been formed, thereby resulting in adjacent and aligned gate electrode segments electrically isolated from each other.

A metal line or region, e.g., a frontside metal region/segment VSS, BL, or BLB, or a backside metal region/segment BM0_VDD or BM0_WL, is a region in the IC layout diagram included in the manufacturing process as part of defining a metal line, or segment, including one or more conductive materials, e.g., polysilicon, copper (Cu), aluminum (Al), tungsten (W), cobalt (Co), ruthenium (Ru), or one or more other metals or other suitable materials, in a given frontside or backside metal layer of the manufacturing process.

In some embodiments, a metal region/segment, e.g., metal region/segment VSS, BL, or BLB, corresponds to a first, or lowermost, frontside metal layer (also referred to as a metal zero layer or frontside metal zero layer in some embodiments), e.g., metal layer M0, or a second or higher level frontside metal layer of the manufacturing process. In some embodiments, a second frontside metal layer is referred to as a metal one layer or frontside metal one layer and a second frontside metal region/segment is referred to as a metal one region/segment.

In some embodiments, a backside metal region/segment, e.g., metal region/segment BM0_VDD or BM0_WL, corresponds to a first, or lowermost, backside metal layer (also referred to as a backside metal zero layer in some embodiments), or a second or higher level backside metal layer of the manufacturing process.

In some embodiments, a metal region/segment corresponds to a component of a power distribution network configured to distribute one or both of a power supply voltage, e.g., a power supply voltage VDD, and/or a reference or ground voltage, e.g., reference voltage VSS. The power distribution network component is electrically connected to one or more features, e.g., additional metal regions/segments and/or via regions/structures, configured to distribute the corresponding power supply or reference voltage and be electrically isolated from IC components outside the distribution network.

A via region/structure, e.g., a via region/structure VD, VG, VDR, or BM0_V, also referred to as a via or interconnect in some embodiments, is a region in the IC layout diagram included in the manufacturing process as part of defining a via/interconnect structure including one or more conductive materials configured to provide an electrical connection between a first, e.g., overlying, conductive structure, e.g., a frontside metal segment VSS, BL, or BLB or backside metal segment BM0_VDD or BM0_WL, and a second, e.g., underlying, conductive structure, e.g., a metal segment, a gate electrode of a gate structure G, a contact structure CT, an interconnect structure ND, or a S/D structure SD, aligned with the first conductive structure in the Z direction.

In some embodiments, a via region/structure VD corresponds to the underlying conductive structure being a S/D region/structure SD, contact region/structure CT, or interconnect region/structure ND.

FIG. 1 is a schematic diagram of SRAM cell 100 included in each of IC layouts/devices 200, 300, and 500, each of FIGS. 2A-2C includes a plan view of IC layout diagram/device 200 and X and Y directions, each of FIGS. 3A and 3E includes a plan view of IC layout diagram/device 300 and the X and Y directions, and FIGS. 3B-3D include cross-sectional views of IC layout diagram/device 300 along respective lines A-A′, B-B′, and C-C′ of FIG. 3B, the X direction and a Z direction.

FIG. 4A is a schematic diagram of an SRAM cell 400, also referred to as IC layout diagram/device 400 in some embodiments, FIG. 4B includes a plan view of IC layout diagram/device 400 and the X and Y directions, and FIG. 4C includes a cross-sectional view of IC layout diagram/device 400 along line D-D′ of FIG. 4B and the X and Z directions, each of FIGS. 5A and 5B includes a plan view of IC layout diagram/device 500 and the X and Y directions, FIG. 6 includes a plan view of IC layout diagram/device 600 and the X and Y directions, and FIG. 7 includes a cross-sectional view of a gate structure 700, also referred to as IC layout diagram/device 700 in some embodiments, and the X and Z directions.

In some cases, for the purpose of clarity, not all instances of each feature included IC layout diagrams/devices 200-700 are labeled in FIGS. 2A-7.

As depicted in FIGS. 1-5B, each of IC layout diagrams/devices 200-500 includes one or more instances of a six-transistor SRAM (6T SRAM) cell, and IC layout diagram/device 600 includes one or more instances of a seven-transistor SRAM (7T-SRAM) cell. In each embodiment, each SRAM cell includes a total of four CFETs arranged as discussed below.

In some embodiments, an IC layout diagram 200-600 corresponds to a single instance of an SRAM cell configured to be stored in a storage device, e.g., a cell library such as cell library 1007 discussed below with respect to IC layout diagram generation system 1000, that at least partially defines the corresponding SRAM device 200-600 within a corresponding area of an IC manufactured based on the cell.

In some embodiments, an IC layout diagram 200-600 corresponds to multiple instances of the SRAM cell configured to be stored in a storage device, e.g., a layout library such as layout diagram(s) 1009 discussed below with respect to IC layout diagram generation system 1000, that at least partially defines corresponding multiple instances of SRAM device 200-600 within one or more corresponding areas of an IC manufactured based on the IC layout diagram.

The features within a given instance of IC layout diagram/device 200, 300, or 500 are configured in accordance with the schematic diagram of SRAM cell 100 depicted in FIG. 1. As depicted in FIG. 1, SRAM cell 100 corresponds to a 6T-SRAM device including two series connections of a p-type pull-up transistor PU and an n-type pull-down transistor PD cross-coupled between a power supply voltage node VDD and a reference voltage node VSS. Corresponding instances of an internal node ND (corresponding to one or more contact and/or interconnect regions/structures ND) are coupled to bit lines BL/BLB through instances of an n-type pass-gate transistor PG, each instance including a gate coupled to a word line WL. In some embodiments, one or both instances of pull-down transistor PG is a p-type transistor and/or one or both instances of pass-gate transistor PG, also referred to as a pass gate PG in some embodiments, is a p-type transistor.

The features within a given instance of IC layout diagram/device 400 are configured in accordance with the schematic diagram of SRAM cell 400 depicted in FIG. 4A. As depicted in FIG. 4A, SRAM cell 400 corresponds to a 6T-SRAM device including two series connections of an n-type pull-up transistor PU and a p-type pull-down transistor PD cross-coupled between power supply voltage node VDD and reference voltage node VSS. The corresponding instances of internal node ND are coupled to bit lines BL/BLB through instances of a p-type pass-gate transistor PG, each instance including a gate coupled to a word line WL.

The features of a given instance of IC layout diagram/device 600 are configured in accordance with the schematic diagram of SRAM cell 100 depicted in FIG. 1 with the addition of a p-type read pass-gate transistor RPG, also referred to as a read pass gate RPG in some embodiments, through which one instance of node ND is coupled to a read bit line (not shown). In some embodiments, read pass-gate transistor RPG is an n-type transistor.

In operation, an instance of IC device 200-600 is configured to receive/output data bits from/to bit lines BL/BLB through pass-gate transistors PG responsive to word line signals received on word line WL, and store the data bits as complementary pairs on internal nodes ND. In some embodiments, bit lines BL/BLB are referred to as complementary bit lines BL/BLB, bit line pair BL/BLB, or complementary bit line pair BL/BLB.

In the embodiments depicted in FIGS. 2-6, each corresponding IC layout diagram/device 200-600 includes a first CFET including a first instance of pass-gate transistor PG positioned at a first elevation along the Z direction, a second CFET including a first pull-down transistor positioned at the first elevation and a first pull-up transistor positioned at a second elevation along the Z direction, a third CFET including a second pull-down transistor positioned at the first elevation and a second pull-up transistor positioned at the second elevation, and a fourth CFET including a second pass-gate transistor positioned at the first elevation.

In the embodiments depicted in FIGS. 2A-6, the first elevation is further along a positive Z direction than the second elevation along the positive Z direction. In some embodiments, the second elevation is further along the positive Z direction than the first elevation.

Each of the first and second pull-down transistors includes an instance of gate G extending in the X direction and including work function configuration WF1, and each of the first and second pass-gate transistors includes an instance of gate G extending in the X direction and including second work function configuration WF1 different from work function configuration WF2.

As depicted in FIGS. 2A-7, a given work function configuration WF1-WF4 refers to either a pattern in a corresponding IC layout diagram 200-600 or to the corresponding arrangement of one or more work function materials in the corresponding IC device 200-600.

As depicted in FIGS. 2C, 3E, 5B, and 6, a work function configuration WF1-WF4 pattern includes one or more regions of the corresponding IC layout diagram 200-600 within which each instance of a corresponding n-type or p-type transistor is configured to include the corresponding one or more work function materials in the corresponding one or more instances of IC device 200-600.

In various embodiments, the one or more regions of a work function configuration WF1-WF4 pattern in an IC layout diagram are arranged based on one or more SRAM cells previously configured to include the corresponding work function configuration WF1-WF4 being placed in the IC layout diagram, or based on the one or more SRAM cells being placed in the IC layout diagram followed by the corresponding work function configuration WF1-WF4 being applied to the previously placed one or more SRAM cells.

FIG. 7 depicts IC layout diagram/device 700, a non-limiting example of an instance of gate G, including one or more work function materials in accordance with one of work function configurations WF1-WF4, represented generically as work function configuration WF in FIG. 7.

In the embodiment depicted in FIG. 7, IC layout diagram/device 700, also referred to as gate 700 in some embodiments, includes the one or more work function materials surrounding three instances of gate dielectric GD, each of which surrounds a corresponding channel region of an active region/area AA. In some embodiments, gate 700 includes fewer or greater than three instances of gate dielectric GD surrounding corresponding channel regions.

As depicted in FIGS. 2A-2C, IC layout diagram/device 200 includes the four CFETs arranged in two rows extending in the X direction (corresponding to instances of gate G) in which a first pull-down transistor PD is aligned with a first pass-gate transistor PG in the X direction and aligned with a second pass-gate transistor PG in the Y direction, and a second pull-down transistor PD is aligned with the first pass-gate transistor in the Y direction and aligned with the second pass-gate transistor PG in the X direction.

Each of FIGS. 2A and 2B depicts a non-limiting example of IC layout diagram/device 200 including an internal node ND configuration on the back side BS of substrate SUB (not labeled). In the embodiment depicted in FIG. 2A, internal nodes ND include instances of backside contact region/structure CT and via region/structure BM0_V, and in the embodiment depicted in FIG. 2B, internal nodes ND include instances of interconnect region/structure ND. Other internal node ND configurations are within the scope of the present disclosure.

As depicted in FIGS. 3A-3E, IC layout diagram/device 300 includes the four CFETs arranged in two rows extending in the X direction (corresponding to instances of gate G) in which a first pull-down transistor PD is aligned with a second pull-down transistor PD in the X direction and aligned with a first pass-gate transistor PG in the Y direction, and a second pass-gate transistor PG is aligned with the first pass-gate transistor PG in the X direction and aligned with the second pull-down transistor PD in the Y direction.

FIG. 3A depicts a non-limiting example of IC layout diagram/device 300 including internal node ND configurations on each of the front side FS and the back side BS of substrate SUB (not labeled). In the embodiment depicted in FIG. 3A, the internal nodes ND include corresponding frontside and backside instances of interconnect region/structure ND and via regions/structures VG and VDR. Other frontside and/or backside internal node ND configurations are within the scope of the present disclosure.

FIG. 3A further depicts non-limiting examples of frontside conductive features reference voltage lines VSS and bit lines BL and BLB, and backside conductive features power supply voltage lines BM0_VDD and word lines BM0_WL, each of which is electrically connected to IC layout diagram/device 300 through corresponding via regions/structures VD and VG.

As depicted in FIGS. 3B-3D, instances of via regions/structures VD and VDR extend in the Z direction through one or more dielectric layers, e.g., interlevel dielectric layers ILD1 and ILD2. Each instance of pass-gate transistor PG and pull-down transistor PD includes an instance of gate G and two S/D regions SD including n-type epitaxial regions/layers N epi, and each instance of pull-up transistor PU includes an instance of gate G and two S/D regions SD including p-type epitaxial regions/layers P epi. A region of substrate SUB at the same elevation along the Z direction as pull-up transistors PU is not included in a transistor and instead includes a dielectric layer ILD.

As depicted in FIGS. 4A-4C, IC layout diagram/device 400 includes the four CFETs having an arrangement similar to that of IC layout diagram/device 300 except that pass-gate transistors PG and pull-down transistors PD are implemented as p-type transistors instead of n-type transistors, and pull-down transistors PD are implemented as n-type transistors instead of p-type transistors.

Accordingly, positioning of pass-gate transistors PG, pull-down transistors PD, pull-down transistors PD, and electrical connections to power supply voltage VDD, reference voltage VSS, bit lines B1 and BLB, and word lines WL with respect to the Z direction are inverted relative to the positioning in IC layout diagram/device 300.

Because IC layout diagrams/devices 300 and 400 have the same positioning with respect to the X and Y directions, the work function configuration pattern of IC layout diagram/device 300 depicted in FIG. 3E applies to IC layout diagram/device 400.

As depicted in FIGS. 5A and 5B, IC layout diagram/device 500 includes the four CFETs arranged in a single column extending in the Y direction in which pull-down transistors PD are positioned between pass-gate transistors PG.

As depicted in FIG. 5A, IC layout diagram/device 500 includes internal node ND configurations on each of the front side FS and the back side BS of substrate SUB (not labeled). In the embodiment depicted in FIG. 3A, the internal nodes ND include corresponding frontside and backside instances of contact region/structure CT, interconnect region/structure ND and via regions/structures VD and VG. Other frontside and/or backside internal node ND configurations are within the scope of the present disclosure.

As depicted in FIG. 6, IC layout diagram/device 600 includes the four CFETs having an arrangement similar to that of IC layout diagram/device 500 with the addition of read pass-gate transistor RPG at the same elevation as pull-up transistors PU. Pull-up transistors PU include instances of gate G including work function configuration WF3, and read pass-gate transistor RPG includes an instance of gate G including work function configuration WF4 different from work function configuration WF3.

In various embodiments, work function configuration WF3 is the same as or different from work function configuration WF1 and/or work function configuration WF4 is the same as or different from work function configuration WF2.

By the configurations discussed above, each of IC layout diagrams/devices 200-600 includes an SRAM device including CFETs in which first and second pull-down transistors PD are positioned at a first Z direction elevation and include gates G having work function configuration WF1, and first and second pass-gate transistors PG are positioned at the first elevation and include gates G having work function configuration WF2 different from work function configuration WF.

By including gates G having different work function configurations WF1 and WF2, pass-gate transistors PG and pull-down transistors PD are capable of having tunable relative threshold voltage levels such that, compared to other approaches, e.g., those in which pass-gate and pull-down transistors have a same threshold voltage level, each of IC layout diagrams/devices 200-600 is capable of having improved read current properties, thereby enabling operation at reduced power supply levels, and for a given power supply voltage level, enabling shortened read windows corresponding to relatively higher operating speeds.

In some embodiments, for a given set of operating conditions, a pull-down transistor PD has a first saturation current Isat PD, a pass-gate transistor PG has a second saturation current Isat PG, and a ratio of Isat PD to Isat PG, referred to as a beta ratio in some embodiments, corresponds to a read window of an SRAM device, with increasing beta ratio values corresponding to increased operating speed.

For the given set of operating conditions, saturation currents Isat PD and Isat PG have values based on the threshold voltages of pull-down transistor PD and pass-gate transistor PG as controlled by work function configurations WF1 and WF2, respectively. By the configurations discussed above, each of IC layout diagrams/devices 200-600 is thereby capable of achieving beta ratio values greater than one, thereby realizing the benefits discussed above.

FIG. 8 is a flowchart of method 800 of manufacturing an IC device, in accordance with some embodiments. Method 800 is operable to form some or all of one or more instances of one or more of IC devices 200-600 discussed above with respect to FIGS. 1-7.

In some embodiments, performing some or all of the operations of method 800 is part of building a plurality of IC devices, e.g., transistors, logic gates, memory cells, interconnect structures, and/or other suitable devices, by performing a plurality of manufacturing operations, e.g., one or more of a lithography, diffusion, deposition, etching, planarizing, or other operation suitable for building the plurality of IC devices in a semiconductor substrate.

In some embodiments, the operations of method 800 are performed in the order depicted in FIG. 8. In some embodiments, the operations of method 800 are performed in an order other than the order depicted in FIG. 8. In some embodiments, one or more additional operations are performed before, during, and/or after the operations of method 800. In some embodiments, performing some or all of the operations of method 800 includes performing one or more operations as discussed below with respect to IC manufacturing system 1100 and FIG. 11.

At operation 802, in some embodiments, a substrate, e.g., a semiconductor substrate is provided. In some embodiments, providing the substrate includes providing substrate SUB discussed above with respect to FIGS. 1-7.

At operation 804, an SRAM device is constructed on a front side of the substrate, the SRAM device including first through fourth CFETs. The first through fourth CFETs are constructed by constructing the first CFET including a first pass-gate transistor positioned at a first elevation along a first direction, the second CFET including a first pull-down transistor positioned at the first elevation and a first pull-up transistor positioned at a second elevation along the first direction, the third CFET including a second pull-down transistor positioned at the first elevation and a second pull-up transistor positioned at the second elevation, and the fourth CFET including a second pass-gate transistor positioned at the first elevation. Constructing each of the first and second pull-down transistors includes forming a gate extending in a second direction perpendicular to the first direction and including a first work function configuration, and constructing each of the first and second pass-gate transistors includes forming a gate extending in the second direction and including a second work function configuration different from the first work function configuration.

In some embodiments, constructing the SRAM device includes constructing one of IC devices 200-600 discussed above with respect to FIGS. 1-7. In some embodiments, constructing the SRAM device includes constructing a plurality of SRAM devices including the SRAM device, e.g., a plurality of one or more of IC devices 200-600 discussed above with respect to FIGS. 1-7.

In some embodiments, forming the gates extending in the second direction and including the first and second work function configurations includes forming instances of gate G including work function configurations WF1 or WF2 and/or including work function configurations WF3 or WF4, as discussed above with respect to FIGS. 1-7

In some embodiments, the first direction extends in a positive direction from a back side of the substrate to the front side of the substrate, and constructing each of the first and second pull-down transistors and the first and second pass-gate transistors includes constructing the first and second pull-down transistors and the first and second pass-gate transistors at the first elevation being further along the first direction in the positive direction than the second elevation, e.g., further along the positive Z direction as discussed above with respect to FIGS. 2-7.

In some embodiments, constructing each of the first and second pull-up transistors includes constructing a p-type transistor, and constructing each of the first and second pull-down transistors and the first and second pass-gate transistors includes constructing an n-type transistor, e.g., as discussed above with respect to FIGS. 1-7.

In some embodiments, constructing the first and second pull-down transistors includes the first pull-down transistor being aligned with the first pass-gate transistor in the second direction and being aligned with the second pass-gate transistor in a third direction perpendicular to each of the first and second directions, and the second pull-down transistor being aligned with the first pass-gate transistor in the third direction and being aligned with the second pass-gate transistor in the second direction, e.g., as discussed above with respect to IC layout diagram/device 200 and FIGS. 2A-2C.

In some embodiments, constructing the first and second pull-down transistors includes the first pull-down transistor being aligned with the second pull-down transistor in the second direction and being aligned with the first pass-gate transistor in the third direction, and the second pass-gate transistor being aligned with the first pass-gate transistor in the second direction and being aligned with the second pull-down transistor in the third direction, e.g., as discussed above with respect to IC layout diagrams/devices 300 and 400 and FIGS. 3A-4C.

In some embodiments, constructing the first and second pull-down transistors includes the first and second pull-down transistors and the first and second pass-gate transistors being aligned with each other in the third direction, and the first and second pull-down transistors being positioned between the first and second pass-gate transistors, e.g., as discussed above with respect to IC layout diagrams/devices 500 and 600 and FIGS. 5A-6.

In some embodiments, constructing each of the first and second pull-up transistors includes forming a gate extending in the second direction and including a third work function configuration, and constructing the first CFET includes constructing a read pass-gate transistor positioned at the second elevation including by forming a gate extending in the second direction and including a fourth work function configuration different from the third work function configuration, e.g., as discussed above with respect to IC layout diagram/device 600 and FIG. 6.

Constructing the SRAM device including the first through fourth CFETs includes performing a plurality of manufacturing processes including one or more of a lithography, diffusion, implantation, deposition, plasma treatment, etching, planarizing, spin coating, soft-baking, exposure, post-baking, developing, rinsing, drying, or other suitable operation.

At operation 806, in some embodiments, electrical connections to the SRAM device are formed. In some embodiments, forming the electrical connections includes forming one or more frontside and/or backside conductive lines, e.g., one or more instances of bit line BL/BLB, word line WL, power supply voltage line VDD, and/or reference voltage line VSS as discussed above with respect to FIGS. 1-7.

In some embodiments, forming the electrical connections includes forming one or more frontside and/or backside vias, e.g., those corresponding to the one or more instances of bit line BL/BLB, word line WL, power supply voltage line VDD, and/or reference voltage line VSS as discussed above with respect to FIGS. 1-7.

Forming the electrical connections includes performing a plurality of manufacturing operations including depositing and patterning one or more photoresist layers, performing one or more etching processes, and performing one or more deposition processes whereby one or more conductive materials are configured to form a plurality of continuous, low resistance structures.

By performing some or all of the operations of method 800, an IC device is manufactured in which an SRAM device includes first and second pass-gate transistors positioned at a first elevation and including gates having a first work function configuration, and first and second pull-down transistors positioned at the first elevation and including gates having a second work function configuration different from the first work function configuration, thereby enabling the realization of the benefits discussed above with respect to IC devices 200-700.

FIG. 9 is a flowchart of method 900 of generating an IC layout diagram, e.g., one or more instances of one or more of IC layout diagrams 200-600 discussed above with respect to FIGS. 1-7, in accordance with some embodiments.

In some embodiments, generating the IC layout diagram includes generating the IC layout diagram corresponding to an IC device, e.g., one or more of IC devices 200-600 discussed above with respect to FIGS. 1-7, manufactured based on the generated IC layout diagram.

In some embodiments, some or all of method 900 is executed by a processor of a computer, e.g., a processor 1002 of an IC layout diagram generation system 1000, discussed below with respect to FIG. 10.

Some or all of the operations of method 900 are capable of being performed as part of a design procedure performed in a design house, e.g., a design house 1120 discussed below with respect to FIG. 11.

In some embodiments, the operations of method 900 are performed in the order depicted in FIG. 9. In some embodiments, the operations of method 900 are performed simultaneously and/or in an order other than the order depicted in FIG. 9. In some embodiments, one or more operations are performed before, between, during, and/or after performing one or more operations of method 900.

At operation 902, in some embodiments, first through fourth CFETs of an SRAM cell are arranged by including first and second pass-gate transistors in a first row and first and second pull-down transistors in a second row, e.g., as discussed above with respect to IC layout diagrams/devices 300 and 400 and FIGS. 3A-4C.

In some embodiments, arranging the first through fourth CFETs of the SRAM cell by including the first and second pass-gate transistors in the first row and the first and second pull-down transistors in the second row includes arranging each of the first and second pass-gate transistors and first and second pull-down transistors being n-type transistors, e.g., as discussed above with respect to IC layout diagram/device 300 and FIGS. 3A-3E.

In some embodiments, arranging the first through fourth CFETs of the SRAM cell by including the first and second pass-gate transistors in the first row and the first and second pull-down transistors in the second row includes arranging each of the first and second pass-gate transistors and first and second pull-down transistors being p-type transistors, e.g., as discussed above with respect to IC layout diagram/device 400 and FIGS. 4A-4C.

At operation 904, in some embodiments, an SRAM cell is positioned in an IC layout diagram, the SRAM cell including first through fourth CFETs including first and second pass-gate transistors and first and second pull-down transistors positioned at a same elevation. In some embodiments, positioning the SRAM cell in the IC layout diagram includes positioning one or more instances of one or more of IC layout diagrams 200-600 discussed above with respect to FIGS. 1-7.

In some embodiments, positioning the SRAM cell in the IC layout diagram includes positioning the SRAM cell including the first through fourth CFETs arranged in two rows and two columns, e.g., as discussed above with respect to IC layout diagrams 200-400 and FIGS. 2A-4C.

In some embodiments, positioning the SRAM cell in the IC layout diagram includes positioning the SRAM cell including the first through fourth CFETs arranged in a single column, e.g., as discussed above with respect to IC layout diagrams 500 and 600 and FIGS. 5A-6.

In some embodiments, positioning the SRAM cell in the IC layout diagram includes positioning the SRAM cell including two or more work function configurations, e.g., two or more of work function configurations WF1-WF4 discussed above with respect to FIGS. 1-7.

In some embodiments, positioning the SRAM cell in the IC layout diagram includes positioning multiple SRAM cell instances in one or more of IC layout diagrams 200-600 as discussed above with respect to FIGS. 1-7.

In some embodiments positioning the SRAM cell in the IC layout diagram includes arranging one or more electrical connections to the SRAM cell, e.g., one or more connections corresponding to power supply voltage VDD, reference voltage VSS, bit lines BL/BLB and/or word lines WL as discussed above with respect to FIGS. 1-7.

At operation 906, in some embodiments, a first pattern of a first work function configuration including each of the first and second pull-down transistors is arranged. In some embodiments, arranging the first pattern of the first work function configuration including each of the first and second pull-down transistors includes arranging the first pattern corresponding to work function configuration WF1 discussed above with respect to FIGS. 1-7.

In some embodiments, arranging the first pattern of the first work function configuration including each of the first and second pull-down transistors includes arranging a third pattern corresponding to work function configuration WF3 discussed above with respect to FIG. 6.

At operation 908, in some embodiments, a second pattern of a second work function configuration including each of the first and second pass-gate transistors is arranged. In some embodiments, arranging the second pattern of the second work function configuration including each of the first and second pass-gate transistors includes arranging the second pattern corresponding to work function configuration WF2 discussed above with respect to FIGS. 1-7.

In some embodiments, arranging the second pattern of the second work function configuration including each of the first and second pass-gate transistors includes arranging a fourth pattern corresponding to work function configuration WF4 discussed above with respect to FIG. 6.

At operation 910, in some embodiments, the IC layout diagram including the SRAM cell(s) is stored in a storage device. In some embodiments, storing the IC layout diagram in the storage device includes storing one or more instances of one or more of IC layout diagrams 200-600, discussed above with respect to FIGS. 1-7, in the storage device.

In some embodiments, storing the IC layout diagram in the storage device includes storing the IC layout diagram in a non-volatile, computer-readable memory or a database, and/or includes storing the IC layout diagram over a network. In some embodiments, storing the IC layout diagram in the storage device includes storing the IC layout diagram in cell library 1007 or layout diagrams 1009 and/or over network 1014 of IC layout diagram generation system 1000, discussed below with respect to FIG. 10.

At operation 912, in some embodiments, one or more manufacturing operations, one or more lithographic exposures, are performed based on the IC layout diagram. Non-limiting examples of performing one or more manufacturing operations, e.g., one or more lithographic exposures, based on the IC layout diagram are discussed above with respect to FIG. 8 and below with respect to FIG. 11.

By executing some or all of the operations of method 900, an IC layout diagram is generated corresponding to an IC device in which first and second pass-gate transistors are positioned at a first elevation and include gates having a first work function configuration, and first and second pull-down transistors are positioned at the first elevation and include gates having a second work function configuration different from the first work function configuration, thereby enabling the realization of the benefits discussed above with respect to IC devices 200-700.

FIG. 10 is a block diagram of IC layout diagram generation system 1000, in accordance with some embodiments. Methods described herein of designing IC layout diagrams in accordance with one or more embodiments are implementable, for example, using IC layout diagram generation system 1000, in accordance with some embodiments.

In some embodiments, IC layout diagram generation system 1000 is a general purpose computing device including a hardware processor 1002 and a non-transitory, computer-readable storage medium 1004. Storage medium 1004, amongst other things, is encoded with, i.e., stores, computer program code 1006, i.e., a set of executable instructions. Execution of instructions 1006 by hardware processor 1002 represents (at least in part) an electronic design automation (EDA) tool which implements a portion or all of a method, e.g., method 600 of generating an IC layout diagram described above with respect to FIG. 6 (hereinafter, the noted processes and/or methods).

Processor 1002 is electrically coupled to computer-readable storage medium 1004 via a bus 1008. Processor 1002 is also electrically coupled to an I/O interface 1010 by bus 1008. A network interface 1012 is also electrically connected to processor 1002 via bus 1008. Network interface 1012 is connected to a network 1014, so that processor 1002 and computer-readable storage medium 1004 are capable of connecting to external elements via network 1014. Processor 1002 is configured to execute computer program code 1006 encoded in computer-readable storage medium 1004 in order to cause IC layout diagram generation system 1000 to be usable for performing a portion or all of the noted processes and/or methods. In one or more embodiments, processor 1002 is a central processing unit (CPU), a multi-processor, a distributed processing system, an application specific integrated circuit (ASIC), and/or a suitable processing unit.

In one or more embodiments, computer-readable storage medium 1004 is an electronic, magnetic, optical, electromagnetic, infrared, and/or a semiconductor system (or apparatus or device). For example, computer-readable storage medium 1004 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 1004 includes a compact disk-read only memory (CD-ROM), a compact disk-read/write (CD-R/W), and/or a digital video disc (DVD).

In one or more embodiments, computer-readable storage medium 1004 stores computer program code 1006 configured to cause IC layout diagram generation system 1000 (where such execution represents (at least in part) the EDA tool) to be usable for performing a portion or all of the noted processes and/or methods. In one or more embodiments, computer-readable storage medium 1004 also stores information which facilitates performing a portion or all of the noted processes and/or methods.

In one or more embodiments, computer-readable storage medium 1004 stores cell library 1007 of cells including such cells as disclosed herein, e.g., memory cells 200-600 discussed above with respect to FIGS. 1-7.

In one or more embodiments, computer-readable storage medium 1004 stores layout diagrams 1009 including such IC layout diagrams as disclosed herein, e.g., IC layout diagrams including memory cells 200-600 discussed above with respect to FIGS. 1-7.

IC layout diagram generation system 1000 includes I/O interface 1010. I/O interface 1010 is coupled to external circuitry. In one or more embodiments, I/O interface 1010 includes a keyboard, keypad, mouse, trackball, trackpad, touchscreen, and/or cursor direction keys for communicating information and commands to processor 1002.

IC layout diagram generation system 1000 also includes network interface 1012 coupled to processor 1002. Network interface 1012 allows system 1000 to communicate with network 1014, to which one or more other computer systems are connected. Network interface 1012 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more IC layout diagram generation systems 1000.

IC layout diagram generation system 1000 is configured to receive information through I/O interface 1010. The information received through I/O interface 1010 includes one or more of instructions, data, design rules, libraries of standard cells, and/or other parameters for processing by processor 1002. The information is transferred to processor 1002 via bus 1008. IC layout diagram generation system 1000 is configured to receive information related to a UI through I/O interface 1010. The information is stored in computer-readable medium 1004 as user interface (UI) 1042.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by IC layout diagram generation system 1000. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

FIG. 11 is a block diagram of IC manufacturing system 1100, and an IC manufacturing flow associated therewith, in accordance with some embodiments. In some embodiments, based on an IC layout diagram, at least one of (A) one or more semiconductor masks or (B) at least one component in a layer of a semiconductor integrated circuit is fabricated using manufacturing system 1100.

In FIG. 11, IC manufacturing system 1100 includes entities, such as a design house 1120, a mask house 1130, and an IC manufacturer/fabricator (“fab”) 1150, that interact with one another in the design, development, and manufacturing cycles and/or services related to manufacturing an IC device 1160. The entities in system 1100 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1120, mask house 1130, and IC fab 1150 is owned by a single larger company. In some embodiments, two or more of design house 1120, mask house 1130, and IC fab 1150 coexist in a common facility and use common resources.

Design house (or design team) 1120 generates an IC design layout diagram 1122. IC design layout diagram 1122 includes various geometrical patterns, e.g., one or more of IC layout diagrams 200-700 discussed above with respect to FIGS. 1-7. The geometrical patterns correspond to patterns of metal, oxide, or semiconductor layers that make up the various components of IC device 1160 to be fabricated. The various layers combine to form various IC features. For example, a portion of IC design layout diagram 1122 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 1120 implements a proper design procedure to form IC design layout diagram 1122. The design procedure includes one or more of logic design, physical design or place and route. IC design layout diagram 1122 is presented in one or more data files having information of the geometrical patterns. For example, IC design layout diagram 1122 can be expressed in a GDSII file format or DFII file format.

Mask house 1130 includes data preparation 1132 and mask fabrication 1144. Mask house 1130 uses IC design layout diagram 1122 to manufacture one or more masks 1145 to be used for fabricating the various layers of IC device 1160 according to IC design layout diagram 1122. Mask house 1130 performs mask data preparation 1132, where IC design layout diagram 1122 is translated into a representative data file (RDF). Mask data preparation 1132 provides the RDF to mask fabrication 1144. Mask fabrication 1144 includes a mask writer. A mask writer converts the RDF to an image on a substrate, such as a mask (reticle) 1145 or a semiconductor wafer 1153. The design layout diagram 1122 is manipulated by mask data preparation 1132 to comply with particular characteristics of the mask writer and/or requirements of IC fab 1150. In FIG. 11, mask data preparation 1132 and mask fabrication 1144 are illustrated as separate elements. In some embodiments, mask data preparation 1132 and mask fabrication 1144 can be collectively referred to as mask data preparation.

In some embodiments, mask data preparation 1132 includes optical proximity correction (OPC) which uses lithography enhancement techniques to compensate for image errors, such as those that can arise from diffraction, interference, other process effects and the like. OPC adjusts IC design layout diagram 1122. In some embodiments, mask data preparation 1132 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1132 includes a mask rule checker (MRC) that checks the IC design layout diagram 1122 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1122 to compensate for limitations during mask fabrication 1144, which may undo part of the modifications performed by OPC in order to meet mask creation rules.

In some embodiments, mask data preparation 1132 includes lithography process checking (LPC) that simulates processing that will be implemented by IC fab 1150 to fabricate IC device 1160. LPC simulates this processing based on IC design layout diagram 1122 to create a simulated manufactured device, such as IC device 1160. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 1122.

It should be understood that the above description of mask data preparation 1132 has been simplified for the purposes of clarity. In some embodiments, data preparation 1132 includes additional features such as a logic operation (LOP) to modify the IC design layout diagram 1122 according to manufacturing rules. Additionally, the processes applied to IC design layout diagram 1122 during data preparation 1132 may be executed in a variety of different orders.

After mask data preparation 1132 and during mask fabrication 1144, a mask 1145 or a group of masks 1145 are fabricated based on the modified IC design layout diagram 1122. In some embodiments, mask fabrication 1144 includes performing one or more lithographic exposures based on IC design layout diagram 1122. In some embodiments, an electron-beam (e-beam) or a mechanism of multiple e-beams is used to form a pattern on a mask (photomask or reticle) 1145 based on the modified IC design layout diagram 1122. Mask 1145 can be formed in various technologies. In some embodiments, mask 1145 is formed using binary technology. In some embodiments, a mask pattern includes opaque regions and transparent regions. A radiation beam, such as an ultraviolet (UV) or EUV beam, used to expose the image sensitive material layer (e.g., photoresist) which has been coated on a wafer, is blocked by the opaque region and transmits through the transparent regions. In one example, a binary mask version of mask 1145 includes a transparent substrate (e.g., fused quartz) and an opaque material (e.g., chromium) coated in the opaque regions of the binary mask. In another example, mask 1145 is formed using a phase shift technology. In a phase shift mask (PSM) version of mask 1145, various features in the pattern formed on the phase shift mask are configured to have proper phase difference to enhance the resolution and imaging quality. In various examples, the phase shift mask can be attenuated PSM or alternating PSM. The mask(s) generated by mask fabrication 1144 is used in a variety of processes. For example, such a mask(s) is used in an ion implantation process to form various doped regions in semiconductor wafer 1153, in an etching process to form various etching regions in semiconductor wafer 1153, and/or in other suitable processes.

IC fab 1150 is an IC fabrication business that includes one or more manufacturing facilities for the fabrication of a variety of different IC products. In some embodiments, IC Fab 1150 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 1150 includes wafer fabrication tools 1152 configured to execute various manufacturing operations on semiconductor wafer 1153 such that IC device 1160 is fabricated in accordance with the mask(s), e.g., mask 1145. In various embodiments, fabrication tools 1152 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1150 uses mask(s) 1145 fabricated by mask house 1130 to fabricate IC device 1160. Thus, IC fab 1150 at least indirectly uses IC design layout diagram 1122 to fabricate IC device 1160. In some embodiments, semiconductor wafer 1153 is fabricated by IC fab 1150 using mask(s) 1145 to form IC device 1160. In some embodiments, the IC fabrication includes performing one or more lithographic exposures based at least indirectly on IC design layout diagram 1122. Semiconductor wafer 1153 includes a silicon substrate or other proper substrate having material layers formed thereon. Semiconductor wafer 1153 further includes one or more of various doped regions, dielectric features, multilevel interconnects, and the like (formed at subsequent manufacturing steps).

In some embodiments, an IC device includes an SRAM device positioned in a substrate, wherein the SRAM device includes a first CFET including a first pass-gate transistor positioned at a first elevation along a first direction, a second CFET including a first pull-down transistor positioned at the first elevation and a first pull-up transistor positioned at a second elevation along the first direction, a third CFET including a second pull-down transistor positioned at the first elevation and a second pull-up transistor positioned at the second elevation, and a fourth CFET including a second pass-gate transistor positioned at the first elevation, wherein each of the first and second pull-down transistors includes a gate extending in a second direction perpendicular to the first direction and including a first work function configuration, and each of the first and second pass-gate transistors includes a gate extending in the second direction and including a second work function configuration different from the first work function configuration. In some embodiments, each of the first and second pull-down transistors and the first and second pass-gate transistors includes an n-type transistor and each of the first and second pull-up transistors includes a p-type transistor. In some embodiments, the first direction extends in a positive direction from a back side of the substrate to a front side of the substrate and the first elevation is further along the first direction in the positive direction than the second elevation. In some embodiments, the first pull-down transistor is aligned with the first pass-gate transistor in the second direction and aligned with the second pass-gate transistor in a third direction perpendicular to each of the first and second directions, and the second pull-down transistor is aligned with the first pass-gate transistor in the third direction and aligned with the second pass-gate transistor in the second direction. In some embodiments, the first pull-down transistor is aligned with the second pull-down transistor in the second direction and aligned with the first pass-gate transistor in a third direction perpendicular to each of the first and second directions, and the second pass-gate transistor is aligned with the first pass-gate transistor in the second direction and aligned with the second pull-down transistor in the third direction. In some embodiments, the SRAM device includes a first internal node including a first contact structure positioned on a front side of the substrate and a second internal node including a second contact structure positioned on a back side of the substrate. In some embodiments, each of the first and second pull-down transistors and the first and second pass-gate transistors includes a p-type transistor and each of the first and second pull-up transistors includes an n-type transistor. In some embodiments, the first and second pull-down transistors and the first and second pass-gate transistors are aligned with each other in a third direction perpendicular to each of the first and second directions, and the first and second pull-down transistors are positioned between the first and second pass-gate transistors. In some embodiments, each of the first and second pull-up transistors includes a gate extending in the second direction and including a third work function configuration, the first CFET includes a read pass-gate transistor positioned at the second elevation, and the read pass-gate transistor includes a gate extending in the second direction and including a fourth work function configuration different from the third work function configuration. In some embodiments, a ratio of a first saturation current corresponding to the first work function configuration to a second saturation current corresponding to the second work function configuration is greater than one.

In some embodiments, a method of manufacturing an IC device includes constructing, on a front side of a substrate, an SRAM device by constructing a first CFET including a first pass-gate transistor positioned at a first elevation along a first direction, constructing a second CFET including a first pull-down transistor positioned at the first elevation and a first pull-up transistor positioned at a second elevation along the first direction, constructing a third CFET including a second pull-down transistor positioned at the first elevation and a second pull-up transistor positioned at the second elevation, and constructing a fourth CFET including a second pass-gate transistor positioned at the first elevation, wherein constructing each of the first and second pull-down transistors includes forming a gate extending in a second direction perpendicular to the first direction and including a first work function configuration, and constructing each of the first and second pass-gate transistors includes forming a gate extending in the second direction and including a second work function configuration different from the first work function configuration. In some embodiments, the first direction extends in a positive direction from a back side of the substrate to a front side of the substrate, constructing each of the first and second pull-up transistors includes constructing a p-type transistor, and constructing each of the first and second pull-down transistors and the first and second pass-gate transistors includes constructing an n-type transistor at the first elevation being further along the first direction in the positive direction than the second elevation. In some embodiments, constructing the first pull-down transistor includes the first pull-down transistor being aligned with the first pass-gate transistor in the second direction and being aligned with the second pass-gate transistor in a third direction perpendicular to each of the first and second directions, and constructing the second pull-down transistor includes the second pull-down transistor being aligned with the first pass-gate transistor in the third direction and being aligned with the second pass-gate transistor in the second direction. In some embodiments, constructing the first pull-down transistor includes the first pull-down transistor being aligned with the second pull-down transistor in the second direction and being aligned with the first pass-gate transistor in a third direction perpendicular to each of the first and second directions, and constructing the second pull-down transistor includes the second pass-gate transistor being aligned with the first pass-gate transistor in the second direction and being aligned with the second pull-down transistor in the third direction. In some embodiments, constructing the first and second pull-down transistors and the first and second pass-gate transistors includes the first and second pull-down transistors and the first and second pass-gate transistors being aligned with each other in a third direction perpendicular to each of the first and second directions, wherein the first and second pull-down transistors are positioned between the first and second pass-gate transistors. In some embodiments, constructing each of the first and second pull-up transistors includes forming a gate extending in the second direction and including a third work function configuration, constructing the first CFET includes constructing a read pass-gate transistor positioned at the second elevation, and constructing the read pass-gate transistor includes forming a gate extending in the second direction and including a fourth work function configuration different from the third work function configuration.

In some embodiments, a method of generating an IC layout diagram includes positioning an SRAM cell in the IC layout diagram, wherein the SRAM cell includes a first CFET including a first pass-gate transistor positioned at a first elevation along a first direction, a second CFET including a first pull-down transistor positioned at the first elevation and a first pull-up transistor positioned at a second elevation along the first direction, a third CFET including a second pull-down transistor positioned at the first elevation and a second pull-up transistor positioned at the second elevation, and a fourth CFET including a second pass-gate transistor positioned at the first elevation, arranging a first pattern of a first work function configuration including gates of each of the first and second pull-down transistors, arranging a second pattern of a second work function configuration different from the first work function configuration including gates of each of the first and second pass-gate transistors, and storing the IC layout diagram including the SRAM cell in a storage device. In some embodiments, positioning the SRAM cell in the IC layout diagram includes positioning the SRAM cell including the first through fourth CFETs arranged in two rows and two columns. In some embodiments, positioning the SRAM cell in the IC layout diagram includes positioning the SRAM cell including the first through fourth CFETs arranged in a single column. In some embodiments, positioning the SRAM cell in the IC layout diagram includes positioning a plurality of SRAM cells including the SRAM cell in the IC layout diagram aligned with each other along a gate direction of the plurality of SRAM cells, arranging the first pattern of the first work function configuration includes arranging a first continuous region of the first work function configuration including corresponding gates of each of corresponding first and second pull-down transistors of each SRAM cell of the plurality of SRAM cells, and arranging the second pattern of the second work function configuration includes arranging a second continuous region of the second work function configuration including corresponding gates of each of corresponding first and second pass-gate transistors of each SRAM cell of the plurality of SRAM cells.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) device comprising:
a static random-access memory (SRAM) device positioned in a substrate, wherein the SRAM device comprises:
a first complementary field-effect transistor (CFET) comprising a first pass-gate transistor positioned at a first elevation along a first direction,
a second CFET comprising a first pull-down transistor positioned at the first elevation and a first pull-up transistor positioned at a second elevation along the first direction,
a third CFET comprising a second pull-down transistor positioned at the first elevation and a second pull-up transistor positioned at the second elevation, and a fourth CFET comprising a second pass-gate transistor positioned at the first elevation,
wherein
each of the first and second pull-down transistors comprises a gate extending in a second direction perpendicular to the first direction and comprising a first work function configuration, and
each of the first and second pass-gate transistors comprises a gate extending in the second direction and comprising a second work function configuration different from the first work function configuration.

2. The IC device of claim 1, wherein
each of the first and second pull-down transistors and the first and second pass-gate transistors comprises an n-type transistor, and
each of the first and second pull-up transistors comprises a p-type transistor.

3. The IC device of claim 1, wherein
the first direction extends in a positive direction from a back side of the substrate to a front side of the substrate, and
the first elevation is further along the first direction in the positive direction than the second elevation.

4. The IC device of claim 1, wherein
the first pull-down transistor is aligned with the first pass-gate transistor in the second direction and aligned with the second pass-gate transistor in a third direction perpendicular to each of the first and second directions, and
the second pull-down transistor is aligned with the first pass-gate transistor in the third direction and aligned with the second pass-gate transistor in the second direction.

5. The IC device of claim 1, wherein
the first pull-down transistor is aligned with the second pull-down transistor in the second direction and aligned with the first pass-gate transistor in a third direction perpendicular to each of the first and second directions, and
the second pass-gate transistor is aligned with the first pass-gate transistor in the second direction and aligned with the second pull-down transistor in the third direction.

6. The IC device of claim 5, wherein the SRAM device further comprises:
a first internal node comprising a first contact structure positioned on a front side of the substrate; and
a second internal node comprising a second contact structure positioned on a back side of the substrate.

7. The IC device of claim 5, wherein
each of the first and second pull-down transistors and the first and second pass-gate transistors comprises a p-type transistor, and
each of the first and second pull-up transistors comprises an n-type transistor.

8. The IC device of claim 1, wherein
the first and second pull-down transistors and the first and second pass-gate transistors are aligned with each other in a third direction perpendicular to each of the first and second directions, and
the first and second pull-down transistors are positioned between the first and second pass-gate transistors.

9. The IC device of claim 8, wherein
each of the first and second pull-up transistors comprises a gate extending in the second direction and comprising a third work function configuration,
the first CFET further comprises a read pass-gate transistor positioned at the second elevation, and
the read pass-gate transistor comprises a gate extending in the second direction and comprising a fourth work function configuration different from the third work function configuration.

10. The IC device of claim 1, wherein
a ratio of a first saturation current corresponding to the first work function configuration to a second saturation current corresponding to the second work function configuration is greater than one.

11. A method of manufacturing an integrated circuit (IC) device, the method comprising:
constructing, on a front side of a substrate, a static random-access memory (SRAM) device, the constructing the SRAM device comprising:
constructing a first complementary field-effect transistor (CFET) comprising a first pass-gate transistor positioned at a first elevation along a first direction,
constructing a second CFET comprising a first pull-down transistor positioned at the first elevation and a first pull-up transistor positioned at a second elevation along the first direction,
constructing a third CFET comprising a second pull-down transistor positioned at the first elevation and a second pull-up transistor positioned at the second elevation, and
constructing a fourth CFET comprising a second pass-gate transistor positioned at the first elevation,
wherein
the constructing each of the first and second pull-down transistors comprises forming a gate extending in a second direction perpendicular to the first direction and comprising a first work function configuration, and
the constructing each of the first and second pass-gate transistors comprises forming a gate extending in the second direction and comprising a second work function configuration different from the first work function configuration.

12. The method of claim 11, wherein
the first direction extends in a positive direction from a back side of the substrate to a front side of the substrate,
the constructing each of the first and second pull-up transistors comprises constructing a p-type transistor, and
the constructing each of the first and second pull-down transistors and the first and second pass-gate transistors comprises constructing an n-type transistor at the first elevation being further along the first direction in the positive direction than the second elevation.

13. The method of claim 11, wherein
the constructing the first pull-down transistor comprises the first pull-down transistor being aligned with the first pass-gate transistor in the second direction and being aligned with the second pass-gate transistor in a third direction perpendicular to each of the first and second directions, and
the constructing the second pull-down transistor comprises the second pull-down transistor being aligned with the first pass-gate transistor in the third direction and being aligned with the second pass-gate transistor in the second direction.

14. The method of claim 11, wherein
the constructing the first pull-down transistor comprises the first pull-down transistor being aligned with the second pull-down transistor in the second direction and being aligned with the first pass-gate transistor in a third direction perpendicular to each of the first and second directions, and
the constructing the second pull-down transistor comprises the second pass-gate transistor being aligned with the first pass-gate transistor in the second direction and being aligned with the second pull-down transistor in the third direction.

15. The method of claim 11, wherein the constructing the first and second pull-down transistors and the first and second pass-gate transistors comprises:
the first and second pull-down transistors and the first and second pass-gate transistors being aligned with each other in a third direction perpendicular to each of the first and second directions,
wherein the first and second pull-down transistors are positioned between the first and second pass-gate transistors.

16. The method of claim 15, wherein
the constructing each of the first and second pull-up transistors comprises forming a gate extending in the second direction and comprising a third work function configuration,
the constructing the first CFET further comprises constructing a read pass-gate transistor positioned at the second elevation, and
the constructing the read pass-gate transistor comprises forming a gate extending in the second direction and comprising a fourth work function configuration different from the third work function configuration.

17. A method of generating an integrated circuit (IC) layout diagram, the method comprising:
positioning a static random-access memory (SRAM) cell in the IC layout diagram, wherein the SRAM cell comprises:
a first complementary field-effect transistor (CFET) comprising a first pass-gate transistor positioned at a first elevation along a first direction;
a second CFET comprising a first pull-down transistor positioned at the first elevation and a first pull-up transistor positioned at a second elevation along the first direction;
a third CFET comprising a second pull-down transistor positioned at the first elevation and a second pull-up transistor positioned at the second elevation; and
a fourth CFET comprising a second pass-gate transistor positioned at the first elevation;
arranging a first pattern of a first work function configuration including gates of each of the first and second pull-down transistors;
arranging a second pattern of a second work function configuration different from the first work function configuration including gates of each of the first and second pass-gate transistors; and
storing the IC layout diagram comprising the SRAM cell in a storage device.

18. The method of claim 17, wherein
the positioning the SRAM cell in the IC layout diagram comprises positioning the SRAM cell comprising the first through fourth CFETs arranged in two rows and two columns.

19. The method of claim 17, wherein
the positioning the SRAM cell in the IC layout diagram comprises positioning the SRAM cell comprising the first through fourth CFETs arranged in a single column.

20. The method of claim 17, wherein
the positioning the SRAM cell in the IC layout diagram comprises positioning a plurality of SRAM cells including the SRAM cell in the IC layout diagram aligned with each other along a gate direction of the plurality of SRAM cells,
the arranging the first pattern of the first work function configuration comprises arranging a first continuous region of the first work function configuration including corresponding gates of each of corresponding first and second pull-down transistors of each SRAM cell of the plurality of SRAM cells, and
the arranging the second pattern of the second work function configuration comprises arranging a second continuous region of the second work function configuration including corresponding gates of each of corresponding first and second pass-gate transistors of each SRAM cell of the plurality of SRAM cells.
